(19) United States
(12) Patent Application Publication
(10) Pub. No.: US 2026/0190357 A1
(43) Pub. Date: Jul. 2, 2026

(54) HIGH-BANDWIDTH MEMORY AND METHOD OF MANUFACTURING THE SAME

(71) Applicant: Samsung Electronics Co., Ltd., Suwon-si (KR)

(72) Inventors: Haseob Seong, Suwon-si (KR); DAWOON JUNG, Suwon-si (KR); Hyeonkyu Ha, Suwon-si (KR)

(21) Appl. No.: 19/322,220

(22) Filed: Sep. 8, 2025

(30) Foreign Application Priority Data
Dec. 27, 2024 (KR) 10-2024-0199312

(51) Int. Cl. H10B 80/00; H01L 23/00; H01L 25/00; H01L 25/065; H01L 25/18

(52) U.S. Cl. CPC H10B 80/00; H10W 90/00; H10W 80/312; H10W 80/327; H10W 90/288; H10W 90/291; H10W 90/792

(57) ABSTRACT

A high-bandwidth memory according to an embodiment includes a base die, a semiconductor stack including a plurality of core dies stacked on the base die, wherein the plurality of core dies has a first width in a horizontal direction, a dummy die on the semiconductor stack, wherein the dummy die includes a first portion having a second width in the horizontal direction, and a second portion above the first portion and having a third width in the horizontal direction, the second width is smaller than the first width, the third width is greater than or equal to the first width, an insulating layer between the semiconductor stack and the dummy die, and a molding material formed on the base die and covering side surfaces of the semiconductor stack, the dummy die, and the insulating layer.

### CROSS-REFERENCE TO RELATED APPLICATION

This application claims priority under 35 U.S.C. § 119 to and the benefit of Korean Patent Application No. 10-2024-0199312 filed in the Korean Intellectual Property Office on Dec. 27, 2024, the entire contents of which are incorporated herein by reference.

### BACKGROUND OF THE INVENTION

### (a) Field of the Invention

The present disclosure relates to a high-bandwidth memory and a method of manufacturing the same.

### (b) Description of the Related Art

The semiconductor industry is seeking to down-size, lighten, and thin the semiconductor packages mounted in electronic devices, while simultaneously pursuing higher speed, multifunction, and large capacity, in response to the demand for down-sizing and lightening of electronic devices. Accordingly, the need for a packaging technology capable of storing more data and transmitting data at a higher speed is increasing, and as such a packaging technology, high-bandwidth memory (HBM), which is formed by stacking multiple individual semiconductor chips, is being developed and used.

High-bandwidth memory HBM is manufactured by placing a memory stack formed by stacking memory dies on a base die, and an important aspect of stacking these memory dies is that the memory dies are coupled with a high I/O density. When the I/O density is increased so that the density of electrical signal connections becomes similar to the density of copper wiring in the semiconductor front-end process, the memory dies may be coupled in the semiconductor back-end process to produce results similar to a single semiconductor chip formed through the semiconductor front-end process.

In this way, in order to stack memory dies with high I/O density, a hybrid bonding process may be applied to the bonding between the memory dies. Hybrid bonding is a method of bonding two devices by fusing the same materials of the two devices using the bonding properties of the same materials. Here, hybrid means that two different types of bonding are made—for example, bonding two devices with a first type of metal-metal bonding and a second type of non-metal-non-metal (e.g., insulator-insulator) bonding. However, when stacking memory dies using hybrid bonding technology, stack voids may occur at the interface between memory dies located at the top of the memory stack as a result of the accumulated surface topography of the stacked multiple memory dies.

To control the occurrence of such stack voids, a dummy die having a relatively large thickness compared to the stacked memory dies may be disposed on the memory stack. Additionally, in order to bond the memory stack and the dummy die, a non-conductive film (NCF) may be disposed between the memory stack and the dummy die, and thermal compression (TC) bonding may be performed on the NCF.

However, after performing thermal compression TC bonding, the NCF may overflow, forming fillets that expose the NCF outside the side surfaces of the memory dies. The fillet formed by the downward flow of the overflowed NCF may contact the base die or the memory dies to form an irregular interface with the molding material, and the irregular interface caused by the fillet may cause delamination between the memory dies or cause cracks to be generated, making the high-bandwidth memory HBM structurally unstable. In addition, the fillet formed by the upward flow of the overflowed NCF may not be covered by the molding material and exposed to the outside, which may oxidize or affect the appearance of the final product, resulting in a reduction in the value of the product.

### SUMMARY OF THE INVENTION

Aspects of the present disclosure provide a high-bandwidth memory HBM having a structure that prevents an overflowed non-conductive film (NCF) from flowing upward and downward.

A high-bandwidth memory according to an embodiment includes a base die, a semiconductor stack including a plurality of core dies stacked on the base die, wherein the plurality of core dies has a first width in a horizontal direction, a dummy die on the semiconductor stack, wherein the dummy die includes a first portion having a second width in the horizontal direction, and a second portion above the first portion and having a third width in the horizontal direction, the second width is smaller than the first width, the third width is greater than or equal to the first width, an insulating layer between the semiconductor stack and the dummy die, and a molding material formed on the base die and covering side surfaces of the semiconductor stack, the dummy die, and the insulating layer.

A high-bandwidth memory according to an embodiment includes a buffer die, a memory stack including a plurality of memory dies stacked on the buffer die, a dummy die on the memory stack, wherein the dummy die includes a first portion, each of side surfaces of the first portion being recessed in a horizontal direction from a corresponding side surface among side surfaces of the plurality of memory dies, the corresponding side surface of the plurality of memory dies facing the same direction as the side surface of the first portion recessed from the corresponding side surface of the plurality of memory dies, and a second portion above the first portion, each of side surfaces of the second portion protruding in a horizontal direction from a corresponding side surface among the side surfaces of the plurality of memory dies, the corresponding side surface of the plurality of memory dies facing the same direction as the side surface of the second portion protruding from the corresponding side surface of the plurality of memory dies, an insulating layer between the memory stack and the dummy die, and a molding material formed on the buffer die and covering side surfaces of the memory stack, the dummy die, and the insulating layer.

A high-bandwidth memory according to an embodiment includes a base die, a semiconductor stack including a plurality of core dies stacked on the base die, wherein the semiconductor stack includes a plurality of core dies and a plurality of interconnection structures, and the plurality of core dies and the plurality of interconnection structures are alternately stacked, an insulating layer on the semiconductor stack, a dummy die on the insulating layer, wherein the dummy die includes a first section, each of side surfaces of the first section being offset inwardly in a horizontal direction by a first length from a corresponding side surface among side surfaces of the plurality of core dies, and a second section above the first section, each of side surfaces of the second section being offset outwardly by a second length from a corresponding side surface among the side surfaces of the plurality of core dies, and a molding material formed on the base die and covering side surfaces of the semiconductor stack, the dummy die, and the insulating layer.

A method of manufacturing a high-bandwidth memory according to an embodiment includes forming a semiconductor stack on a base die by stacking a plurality of core dies on a base die, wherein the plurality of core dies has a first width in a horizontal direction, attaching a dummy die with an insulating layer on the semiconductor stack, wherein the dummy die includes a first portion having a second width in the horizontal direction, and a second portion above the first portion and having a third width in the horizontal direction, wherein the second width is smaller than the first width, and the third width is larger than or equal to the first width, and molding the semiconductor stack, the dummy die, and the insulating layer with a molding material on the base die.

A high-bandwidth memory (HBM) may be provided, wherein a dummy die is disposed on a memory die, the dummy die including a first portion having a second width smaller than a first width of a memory die, and a second portion above the first portion and having a third width larger than the first width of the memory die. As a result, the overflowed NCF is primarily prevented from flowing downward by the memory stack, and secondarily prevented from flowing upward by the second portion.

Therefore, the embodiments may prevent the overflowed NCF from flowing downward, causing delamination between memory dies, or generating cracks, adversely affecting the internal circuits of the base die or memory die.

In addition, the overflowed NCF may flow upward, preventing the fillet from being exposed to the outside and oxidized, or affecting the appearance of the final product.

### BRIEF DESCRIPTION OF THE DRAWINGS

FIG. 1 is a cross-sectional view of a high-bandwidth memory according to an embodiment.

FIG. 2 is a top plan view illustrating an upper surface of the high-bandwidth memory of FIG. 1 according to an embodiment.

FIG. 3 is a cross-sectional view illustrating a high-bandwidth memory of an embodiment.

FIG. 4 is a top plan view illustrating an upper surface of the high-bandwidth memory of FIG. 3 according to an embodiment.

FIG. 5 is a cross-sectional view illustrating a high-bandwidth memory of an embodiment.

FIG. 6 is a top plan view illustrating an upper surface of the high-bandwidth memory of FIG. 5 according to an embodiment.

FIG. 7 is a cross-sectional view illustrating a method of manufacturing a dummy die according to an embodiment.

FIG. 8 is a cross-sectional view illustrating a method of manufacturing a dummy die according to an embodiment.

FIGS. 9 to 14 are cross-sectional views illustrating a method of forming the high-bandwidth memory of FIG. 1 according to an embodiment.

FIG. 15 is a cross-sectional view illustrating a high-bandwidth memory of an embodiment.

FIGS. 16 to 20 are cross-sectional views illustrating a method of forming the high-bandwidth memory of FIG. 15 according to an embodiment.

### DETAILED DESCRIPTION OF THE EMBODIMENTS

Hereinafter, the present disclosure will be described in detail with reference to the accompanying drawings, in which embodiments of the present disclosure are shown. As those skilled in the art would realize, the described embodiments may be modified in various different ways, all without departing from the spirit or scope of the present disclosure.

The drawings and descriptions are to be regarded as illustrative in nature and not restrictive, and like reference numerals designate like elements throughout the specification.

In addition, size and thickness of each constituent element in the drawings are arbitrarily illustrated for better understanding and ease of description, and the following embodiments are not limited thereto.

Throughout this specification and the claims that follow, when it is stated that an element is “coupled” to another element, it includes not only the case of being “directly coupled” but also “indirectly coupled” with another element therebetween. In addition, unless explicitly stated to the contrary, the word “comprise,” and variations such as “comprises” and “comprising,” should be understood to imply the inclusion of stated elements but not the exclusion of any other elements.

It should be understood that when an element such as a layer, film, region, or substrate is referred to as being “on” or “above” another element, it can be “directly on” the other element or intervening elements may also be present. In contrast, when an element is referred to as being “directly on” another element, there are no intervening elements present. Further, when an element is referred to as being “on” or “above” a reference element, it can be positioned above or below the reference element, and it is not necessarily referred to as being positioned “on” or “above” it in a direction opposite to gravity. For example, spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Components described as thermally connected or in thermal communication are arranged such that heat will follow a path between the components to allow the heat to transfer from the first component to the second component. Simply because two components are part of the same device or package does not make them thermally connected. In general, components which are heat-conductive and directly connected to other heat-conductive or heat-generating components (or connected to those components through intermediate heat-conductive components or in such close proximity as to permit a substantial transfer of heat) will be described as thermally connected to those components, or in thermal communication with those components. On the contrary, two components with heat-insulative materials therebetween, which materials significantly prevent heat transfer between the two components, or only allow for incidental heat transfer, are not described as thermally connected or in thermal communication with each other. The terms “heat-conductive” or “thermally-conductive” do not apply to a particular material simply because it provides incidental heat conduction, but are intended to refer to materials that are typically known as good heat conductors or known to have utility for transferring heat, or components having similar heat conducting properties as those materials.

Further, throughout the specification, the phrase “in a plan view” means viewing a target portion from the top, and the phrase “in a cross-sectional view” means viewing a cross-section formed by vertically cutting a target portion and viewing it from the side.

Hereinafter, a high-bandwidth memory (HBM) 100 and a method of manufacturing the high-bandwidth memory HBM 100 according to an embodiment will be described with reference to the drawings.

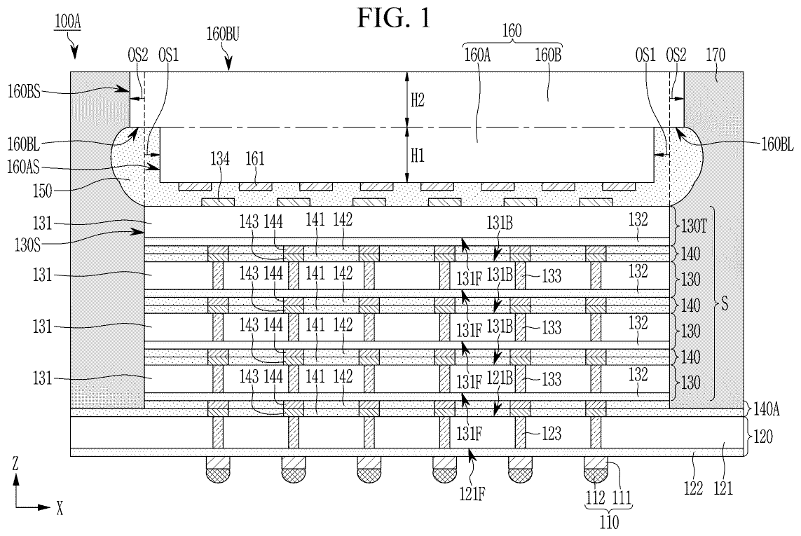

FIG. 1 is a cross-sectional view illustrating a high-bandwidth memory HBM 100A of an embodiment.

Referring to FIG. 1, the high-bandwidth memory HBM 100A may include bump structures 110, a base die (logic die; buffer die) 120, a memory stack (semiconductor stack) S, first pads 134, an insulating member/layer 150, a dummy die (dummy structure) 160, second pads 161, and a molding material/layer 170. The high-bandwidth memory HBM 100A is a high-performance three-dimensional (3D) stacked dynamic random-access memory (DRAM). The high-bandwidth memory HBM 100A has multiple memory channels through the memory stack S manufactured by vertically stacking memory dies 130, which may simultaneously implement low latency and high bandwidth compared to conventional DRAM products, and may reduce the total area occupied by individual DRAMs on a substrate, which is advantageous for high bandwidth-to-area ratio and may reduce power consumption.

The bump structures 110 may be disposed between the base die 120 and an external device. For example, the bump structures 110 may be disposed on a bottom surface the base die 120. Each of the bump structures 110 is disposed on a corresponding wiring among the wirings of a front side structure 122 of the base die 120, and may electrically connect the corresponding wiring among the wirings of the front side structure 122 of the base die 120 to an external device. Each of the bump structures 110 may include a bump pillar 111 and a solder ball 112. In an embodiment, the bump structures 110 may include or may be microbumps. The bump pillar 111 may be disposed between a corresponding wiring among the wirings of the front side structure 122 of the base die 120 and the solder ball 112. In an embodiment, the bump pillar 111 may be formed of copper, or a copper alloy including silver, chromium, nickel, tin, gold, and a combination thereof. In an embodiment, the solder ball 112 may include at least one of tin, silver, lead, nickel, copper, and an alloy thereof.

The base die 120 may be disposed between the memory stack S and the external device. The base die 120 may be a buffer die. When data is exchanged between devices without a buffer die with different data processing speeds, processing units, and usage times, data loss may occur due to differences in data processing speeds, processing units, and usage times between each device. To prevent such loss, the base die 120 may be disposed between the memory dies 130 and the external device, such that information from the transfer of data to and from the memory dies 130 and the external device may be temporarily stored in the base die 120. When transmitting data to or receiving data from the memory dies 130, the base die 120 may sequentially pass the data after aligning the order of the data.

The base die 120 may include a die base 121, the front side structure 122, and first through silicon vias (TSVs) 123. The die base 121 may include a front side 121F facing the bump structures 110 and a back side 121B opposite the front side 121F. The die base 121 may be a die formed from a wafer. In an embodiment, the die base 121 may include silicon or another semiconductor material.

The front structure 122 may be disposed between the die base 121 and the bump structures 110. The front structure 122 may include an active layer and a wiring layer. The active layer may be disposed on the front side of the die base 121. The active layer may include an integrated circuit structure having integrated circuit regions. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the active layer. The wiring layer may include signal wiring lines, power wiring lines, contact plugs, and an intermetal dielectric (IMD).

The first TSVs 123 may be disposed within the die base 121. Each of the first TSVs 123 may be disposed between a wiring layer of the front side structure 122 and a corresponding one of first bonding pads 143 of a first interconnection structure 140A on the back side 121B of the die base 121. Each of the first TSVs 123 may electrically connect a wiring layer of the front side structure 122 to the corresponding first bonding pad 143 of the first interconnection structure 140A on the back side 121B of the die base 121. In an embodiment, the first TSVs 123 may include at least one of tungsten, aluminum, copper, and an alloy thereof.

The first interconnection structure 140A may be disposed between the back side 121B of the die base 121 and the memory stack S. The first interconnection structure 140A may include a back side silicon layer 141 on the back side 121B of the die base 121, a front side silicon layer 142 on a front side structure 132 of a memory die 130, back side bonding pads 143 on the back side 121B of the die base 121, and front side bonding pads 144 on the front side structure 132 of the memory die 130. The back side silicon layer 141 may be directly bonded to the front side silicon layer 142. The back side silicon layer 141 may surround and insulate the back side bonding pads 143. The front side silicon layer 142 may surround and insulate the front side bonding pads 144. In an embodiment, the back side silicon layer 141 and the front side silicon layer 142 may include at least one of silicon oxide and silicon nitride. In an embodiment, the back side silicon layer 141 and the front side silicon layer 142 may include SiO₂, SiN, or SiCN.

The back side bonding pads 143 may be disposed to penetrate the back side silicon layer 141. The level of bonding surfaces of the back side bonding pads 143 may be the same as the level of the bonding surface of the back side silicon layer 141. The side surfaces of the back side bonding pads 143 may be surrounded by and/or contact the back side silicon layer 141. Each of the back side bonding pads 143 may be electrically connected to the corresponding first TSV 123 among the first TSVs 123. Each of the back side bonding pads 143 may be directly bonded to a corresponding front side bonding pad 144 among the front side bonding pads 144. The front side bonding pads 144 may be disposed through the front side silicon layer 142. The level of the bonding surfaces of the front side bonding pads 144 may be the same as the level of the bonding surface of the front side silicon layer 142. The side surfaces of the front side bonding pads 144 may be surrounded by and/or contact the front side silicon layer 142. Each of the front side bonding pads 144 may be electrically connected to a corresponding wiring among the wirings of the front side structure 132 of the memory die 130. Electrical connection may be made between the base die 120 and the memory stack S by direct bonding between the back side bonding pads 143 and the front side bonding pads 144. In an embodiment, the back side bonding pads 143 and the front side bonding pads 144 may include a conductive material capable of applying copper bonding or hybrid bonding.

The memory stack S may be disposed on the base die 120. The memory stack S may include memory dies 130 stacked vertically and second interconnection structures 140 alternating with the memory dies 130. Side surfaces 130S of the memory dies 130 (or the memory stack S) may not contact the insulating member 150. The side surfaces 130S of the memory dies 130 (or the memory stack S) may be in contact with the molding material 170. In FIG. 1, the memory stack S including four memory dies 130 is disclosed, but the inventive concept is not limited thereto, and the memory stack S including a greater or lesser number of memory dies 130 may be included within the scope of the present disclosure. For example, the memory stack S may include four, eight, twelve, sixteen, or twenty memory dies 130.

A memory die (semiconductor die; core die; 130) in the memory stack S may include a memory die base 131, the front side structure 132, and second TSVs 133. A memory die (e.g., an uppermost memory die) 130T positioned at the top of the memory stack S may not include the second TSVs 133. In an embodiment, the memory die 130 may include a DRAM. For example, the memory die 130 may be a DRAM die/chip.

The memory die base 131 may include a front side 131F facing the bump structures 110 and a back side 131B opposite the front side 131F. The memory die base 131 may be a die formed from a wafer. In an embodiment, the memory die base 131 may include silicon or another semiconductor material.

The front side structure 132 may be disposed on the front side 131F of the memory die base 131. The front side structure 132 may include an active layer and a wiring layer. The active layer may be disposed on the front side of the memory die base 131. The active layer may include an integrated circuit structure having integrated circuit regions. In an embodiment, the integrated circuit structure may include at least one of an active device and a passive device. In an embodiment, the integrated circuit structure may include a gate structure, a source region, and a drain region. In an embodiment, the integrated circuit structure may include at least one of a transistor, a diode, a capacitor, an inductor, and a resistor. The wiring layer may be disposed on the active layer. The wiring layer may include signal wiring lines, power wiring lines, contact plugs, and the IMD.

The second TSVs 133 may be disposed within the memory die base 131. Each of the second TSVs 133 may be disposed between a wiring layer of the front side structure 132 and a corresponding one of the first bonding pads 143 of the second interconnection structure 140 on the back side 131B of the memory die base 131. Each of the second TSVs 133 may electrically connect a wiring layer of the front side structure 132 to the corresponding first bonding pad 143 of first bonding pads 143 of the second interconnection structure 140 on the back side 131B of the memory die base 131. In an embodiment, the second TSVs 133 may include at least one of tungsten, aluminum, copper, and an alloy thereof.

The second interconnection structures 140 may be alternately stacked with the memory dies 130. Each of the second interconnection structures 140 may be disposed between a back side 131B of a memory die base 131 of a memory die 130 and a front side structure 132 of an adjacent memory die 130. Each of the second interconnection structures 140 may include a first silicon layer (the back side silicon layer) 141 on the back side 131B of the memory die base 131, a second silicon layer (the front side silicon layer) 142 on the front side structure 132 of the memory die 130, the first bonding pads (the back side bonding pads) 143 on the back side 131B of the memory die base 131, and second bonding pads (the front side bonding pads) 144 on the front side structure 132 of the memory die 130. The first silicon layer 141 may be directly bonded to the second silicon layer 142. The first silicon layer 141 may surround and insulate the first bonding pads 143. The second silicon layer 142 may surround and insulate the second bonding pads 144. In an embodiment, the first silicon layer 141 and the second silicon layer 142 may include at least one of silicon oxide and silicon nitride. In an embodiment, the first silicon layer 141 and the second silicon layer 142 may include SiO₂, SiN, or SiCN.

The first bonding pads 143 may be disposed through the first silicon layer 141. The level of the bonding surfaces of the first bonding pads 143 may be the same as the level of the bonding surface of the first silicon layer 141. The side surfaces of the first bonding pads 143 may be surrounded by and/or contact the first silicon layer 141. Each of the first bonding pads 143 may be electrically connected to a corresponding second TSV 133 among the second TSVs 133. Each of the first bonding pads 143 may be directly bonded to a corresponding second bonding pad 144 among the second bonding pads 144. The second bonding pads 144 may be disposed through the second silicon layer 142. The level of the bonding surfaces of the second bonding pads 144 may be the same as the level of the bonding surface of the second silicon layer 142. The side surfaces of the second bonding pads 144 may be surrounded by and/or contact the second silicon layer 142. Each of the second bonding pads 144 may be electrically connected to a corresponding wiring among the wirings of the memory die 130. Electrical connection between the memory dies 130 may be made by direct bonding between the first bonding pads 143 and the second bonding pads 144. In an embodiment, the first bonding pads 143 and the second bonding pads 144 may include copper or a conductive material capable of applying hybrid bonding.

The first pads 134 may be disposed on the memory stack S. The first pads 134 may be disposed on the memory die 130T positioned at the top of the memory stack S. The first pads 134 may be covered by the insulating member 150. For example, the insulating member 150 may be an insulating layer, e.g., an electrically-insulating layer formed of an electrically-insulating material. The first pads 134 may be electrically isolated from other components, including the memory die 130T positioned at the top of the memory stack S. The first pads 134 are thermally connected to (e.g., in thermal communication with) the memory stack S and may transfer heat generated by the memory stack S to a dummy die 160 through the insulating member 150 and the second pads 161. The first pads 134 may be covered by the insulating member 150 on the memory die 130T positioned at the top of the memory stack S. The upper surface and side surfaces of each of the first pads 134 may be surrounded by and/or contact the insulating member 150. In an embodiment, the first pads 134 may include a conductive material having high thermal conductivity. In an embodiment, the first pads 134 may include at least one of copper, aluminum, silver, tin, gold, nickel, lead, titanium, and an alloy thereof.

The insulating member 150 may be disposed between the memory stack S and the dummy die 160. The insulating member 150 may surround and cover the first pads 134 and the second pads 161. The insulating member 150 may contact at least a portion of each of side surfaces 160AS of a first portion 160A of the dummy die 160. The insulating member 150 may contact at least a portion of a lower surface (a second surface) 160BL of a second portion 160B of the dummy die 160. The insulating member 150 may not contact each of side surfaces 160BS of the second portion 160B of the dummy die 160. The insulating member 150 may not contact the side surfaces 130S of the memory dies 130 (the memory stack S).

The insulating member 150 may include a material having a high dielectric constant. The insulating member 150 may allow the memory stack S and the first pads 134 to be in thermal communication, and may allow the heat generated by the memory stack S to be transferred through the second pads 161 to the dummy die 160. In an embodiment, the insulating member 150 may include or may be a non-conductive film (NCF). In an embodiment, the insulating member 150 may include at least one of a thermosetting resin, a curing agent, a catalyst, a flux, a thermoplastic resin, and an inorganic filler. In an embodiment, the inorganic filler may include alumina. The insulating member 150 may have a small enough thickness to allow heat to transfer from one side to another between two thermally conductive components such as between the dummy die 160 and/or second pads 161 and the first pads 134 and/or the memory stack S.

The dummy die (dummy structure) 160 may be disposed on the memory stack S. The dummy die 160 may be attached to the memory stack S by the insulating member 150. The dummy die 160 may be thermally connected (e.g., in thermal communication with) to the memory stack S through the first pads 134, the insulating member 150, and the second pads 161, and may release heat transferred from the memory stack S to the outside. In an embodiment, the dummy die 160 may include or be a heat dissipation structure. In an embodiment, the heat dissipation structure may include or may be a heat slug, a heat sink, or a heat spreader. For example, the dummy die 160 may be a heat-dissipating die in certain embodiments. In an embodiment, the heat dissipation structure may include or may be formed of a conductive material having high thermal conductivity. In an embodiment, the dummy die 160 may include or may be formed of a metal such as at least one of copper, aluminum, silver, tin, gold, nickel, lead, titanium, and an alloy thereof.

The dummy die 160 may include the first portion (first structure) 160A and the second portion (second structure) 160B on the first portion 160A. The first portion 160A and the second portion 160B may have a shape that is integrally formed, e.g., as one body without a visible/explicit boundary between the first portion 160A and the second portion 160B. The first portion 160A of the dummy die 160 may have a first height H1 (e.g., thickness) in a vertical direction (Z direction). The second portion 160B of the dummy die/structure may have a second height H2 (e.g., thickness) in the vertical direction (Z direction). In an embodiment, the ratio of the first height H1 to the second height H2 may be in a range from 1:9 to 9:1.

Each side surface 160AS of the side surfaces 160AS of the first portion 160A may be recessed in a horizontal direction (X direction and/or Y direction) from a corresponding side surface 130S of the side surfaces 130S of the memory dies 130 (memory stack S). For example, the corresponding side surface 130S of the memory dies 130 to a side surface 160AS of the first portion 160A may be a side surface facing the same direction as the side surface 160AS of the first portion 160A as shown in FIG. 1. Each side surface 160AS of the side surfaces 160AS of the first portion 160A may be offset/shifted OS1 inwardly in the horizontal direction (X direction and/or Y direction) from the corresponding side surface 130S of the side surfaces 130S of the memory dies 130 (memory stack S), e.g., in a plan view. Each side surface 160AS of the side surfaces 160AS of the first portion 160A may be covered at least partially by the insulating member 150.

Each side surface 160BS of the side surfaces 160BS of the second portion 160B may protrude in the horizontal direction (X direction and/or Y direction) from the corresponding side surface 130S of the side surfaces 130S of the memory dies 130 (memory stack S). Each side surface 160BS of the side surfaces 160BS of the second portion 160B may be offset/shifted OS2 outwardly in the horizontal direction (X direction and/or Y direction) from the corresponding side surface 130S of the side surfaces 130S of the memory dies 130 (memory stack S), e.g., in a plan view. Each side surface 160BS of the side surfaces 160BS of the second portion 160B may contact the molding material 170 without being in contact with the insulating member 150. For example, the entire side surfaces 160BS of the second portion 160B may contact the molding material 170. The second portion 160B may include a first surface 160BU exposed to the outside from the molding material 170, and a second surface 160BL that is opposite to the first surface 160BU and extends between the side surfaces 160AS of the first portion 160A and the side surfaces 160BS of the second portion 160B. The second surface 160BL may at least partially contact the insulating member 150.

The second pads 161 may be disposed on the surface (e.g., on the bottom surface) of the dummy die 160 facing the memory stack S. The second pads 161 may be covered by the insulating member 150. The second pads 161 may be electrically isolated from other components, including the first pads 134 and the dummy die 160. The second pads 161 may be spaced apart from the first pads 134. The second pads 161 are thermally connected to (e.g., in thermal communication with) the memory stack S through the first pads 134 and the insulating member 150, and may transfer heat generated by the memory stack S to the dummy die 160. The lower surface and side surface of each of the second pads 161 may be surrounded by and/or contact the insulating member 150. In an embodiment, the second pads 161 may include a conductive material having high thermal conductivity. In an embodiment, the second pads 161 may include at least one of copper, aluminum, silver, tin, gold, nickel, lead, titanium, and an alloy thereof.

The molding material 170 may cover the memory stack S, the insulating member 150, and the dummy die 160 on the base die 120. For example, the molding material 170 may be formed on the base die 120 and cover side surfaces of the memory stack S, the insulating member 150, and the dummy die 160. The first surface 160BU of the dummy die 160 may be exposed from the molding material 170 and may have a level that is the same as the level of the upper surface of the molding material 170.

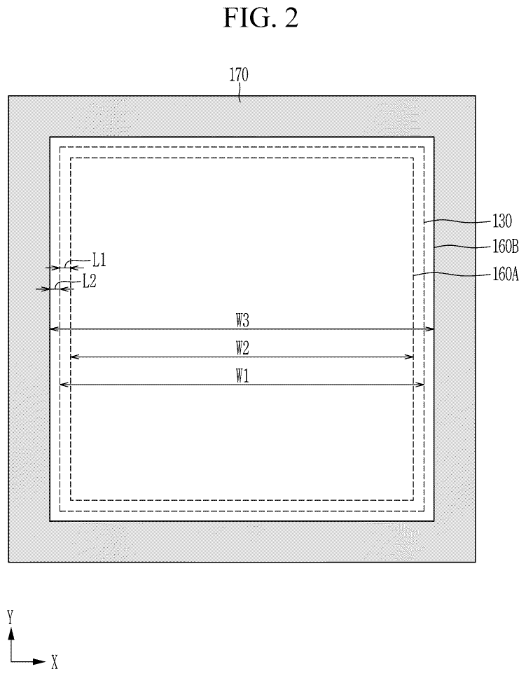

FIG. 2 is a top plan view illustrating an upper surface of the high-bandwidth memory HBM 100A of FIG. 1 according to an embodiment.

Referring to FIG. 2, the memory dies 130 may have a first width W1 in the horizontal direction (X direction and/or Y direction). The first portion 160A of the dummy die 160 may be a first vertical section of the dummy die 160 that has a second width W2 in the horizontal direction (X direction and/or Y direction). The second portion 160B of the dummy die 160 may be a second vertical section of the dummy die 160 that has a third width W3 in the horizontal direction (X direction and/or Y direction). The second width W2 may be smaller than the third width W3. The first width W1 may be, for each memory die 130, a distance between opposite sidewalls of the memory die 130 in a first horizontal direction (e.g., the X direction). The second width W2 may be a distance between opposite sidewalls of the first portion 160A in the first horizontal direction (e.g., the X direction). The third width W3 may be a distance between opposite sidewalls of the second portion 160B in the first horizontal direction (e.g., the X direction). The second width W2 may be smaller than the first width W1. The third width W3 may be larger than the first width W1. The first portion 160A of the dummy die 160 may be completely overlapped by the memory stack S or the memory dies 130 in the vertical direction (Z direction). For example, the whole of the first portion 160A of the dummy die 160 may overlap the memory stack S or the memory dies 130 in the vertical direction. The footprint of the first portion 160A of the dummy die 160 may be included in or be within the footprint of the memory stack S and/or the footprint of the memory dies 130. The memory stack S or the memory dies 130 may be completely overlapped by the second portion 160B of the dummy die 160 in the vertical direction (Z direction). For example, the whole of the memory stack S or the memory dies 130 may overlap the second portion 160B of the dummy die 160 in the vertical direction. The footprint of the memory stack S or the footprint of the memory dies 130 may be included in or be within the footprint of the second portion 160B of the dummy die 160.

Each side surface 160AS of the side surfaces 160AS of the first portion 160A may be offset/shifted OS1 inwardly by a first length L1 in the horizontal direction (X direction and/or Y direction) from the corresponding side surface 130S of the side surfaces 130S of the memory dies 130 (the memory stack S), e.g., in a plan view. In an embodiment, the first length L1 may be in a range of about 0.5 mm to about 1.3 mm. Each side surface 160BS of the side surfaces 160BS of the second portion 160B may be offset/shifted OS2 outwardly by a second length L2 in the horizontal direction (X direction and/or Y direction) from the corresponding side surface 130S of the side surfaces 130S of the memory dies 130 (memory stack S), e.g., in a plan view. In an embodiment, the second length L2 may be in a range of about 0.5 mm to about 1.3 mm.

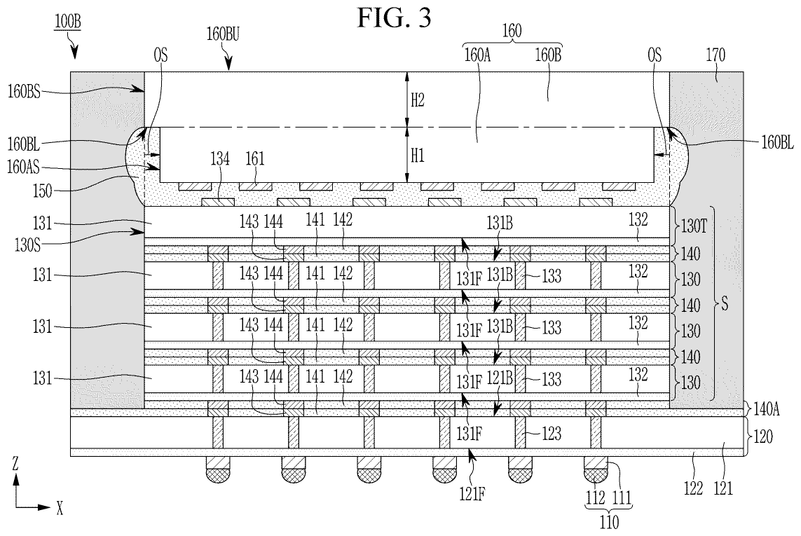

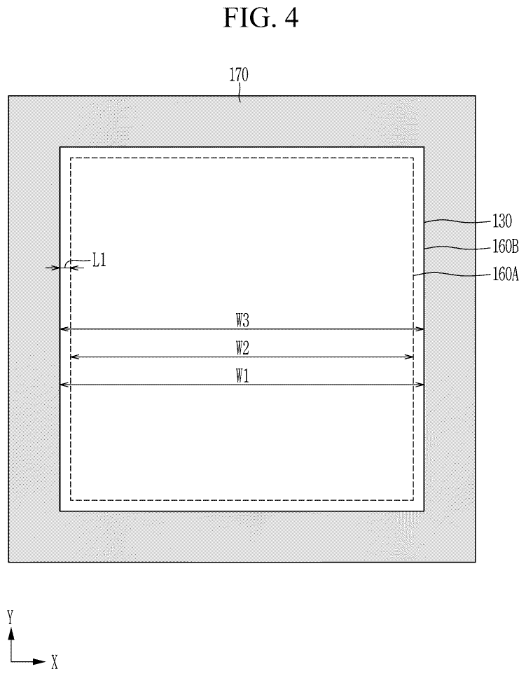

FIG. 3 is a cross-sectional view illustrating a high-bandwidth memory HBM 100B of an embodiment. FIG. 4 is a top plan view illustrating an upper surface of the high-bandwidth memory HBM 100B of FIG. 3 according to an embodiment.

Referring to FIGS. 3 and 4, each side surface 160AS of the side surfaces 160AS of the first portion 160A in the dummy die 160 may be recessed in the horizontal direction (X direction and/or Y direction) from the corresponding side surface 130S of the side surfaces 130S of the memory dies 130 (memory stack S). Each side surface 160AS of the side surfaces 160AS of the first portion 160A may be offset OS inwardly in the horizontal direction (X direction and/or Y direction) from the corresponding side surface 130S of the side surfaces 130S of the memory dies 130 (memory stack S). Each side surface 160BS of the side surfaces 160BS of the second portion 160B of the dummy die 160 may be at the same position as the corresponding side surface 130S of the side surfaces 130S of the memory dies 130 (memory stack S), e.g., in a plan view as shown in FIG. 4. For example, each side surface 160BS of the second portion 160B of the dummy die 160 may vertically overlap a corresponding side surface 130S of the memory dies 130.

The memory dies 130 may have the first width W1 in the horizontal direction (X direction and/or Y direction). The first portion 160A of the dummy die 160 may have the second width W2 in the horizontal direction (X direction and/or Y direction). The second portion 160B of the dummy die 160 may have the third width W3 in the horizontal direction (X direction and/or Y direction). The second width W2 may be smaller than the first width W1. The third width W3 may be equal to the first width W1. The first portion 160A of the dummy die 160 may be completely overlapped by the memory stack S or the memory dies 130 in the vertical direction (Z direction). For example, the whole of the first portion 160A of the dummy die 160 may overlap the memory stack S or the memory dies 130 in the vertical direction. The footprint of the first portion 160A of the dummy die 160 may be included in or be within the footprint of the memory stack S or the footprint of the memory dies 130. The memory stack S or the memory dies 130 may completely overlap or match the second portion 160B of the dummy die 160 in the vertical direction (Z direction). The footprint of the memory stack S or the footprint of the memory dies 130 may be included in or may match the footprint of the second portion 160B of the dummy die 160.

Each side surface 160AS of the side surfaces 160AS of the first portion 160A may be offset/shifted OS1 inwardly by a first length L1 in the horizontal direction (X direction and/or Y direction) from the corresponding side surface 130S of the side surfaces 130S of the memory dies 130 (the memory stack S), e.g., in a plan view. In an embodiment, the first length L1 may be in a range of about 0.5 mm to about 1.3 mm. Each side surface 160BS of the side surfaces 160BS of the second portion 160B may match the corresponding side surface 130S of the side surfaces 130S of the memory dies 130 (memory stack S). For example, each side surface 160BS of the second portion 160B may vertically overlap a corresponding side surface 130S of the memory dies 130.

For contents/features other than those described above for the high-bandwidth memory HBM 100B of the embodiments of FIGS. 3 and 4, the contents/features described for the HBM 100A of FIGS. 1 and 2 may be applied.

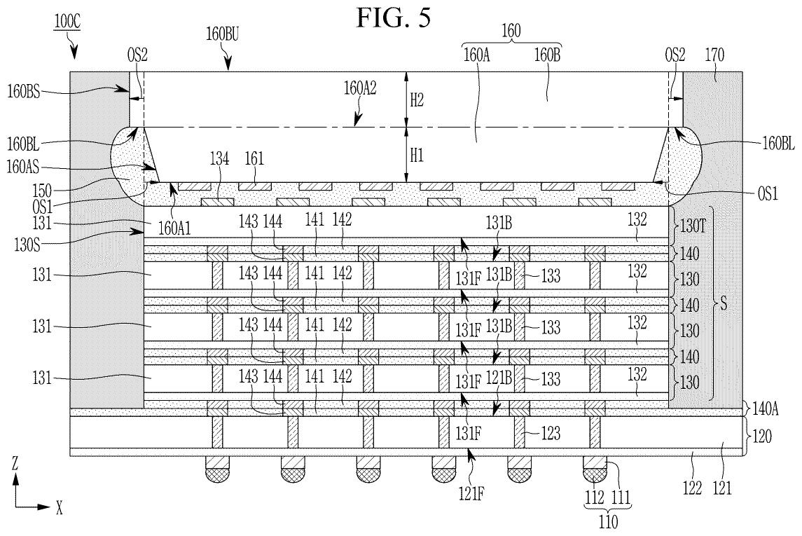

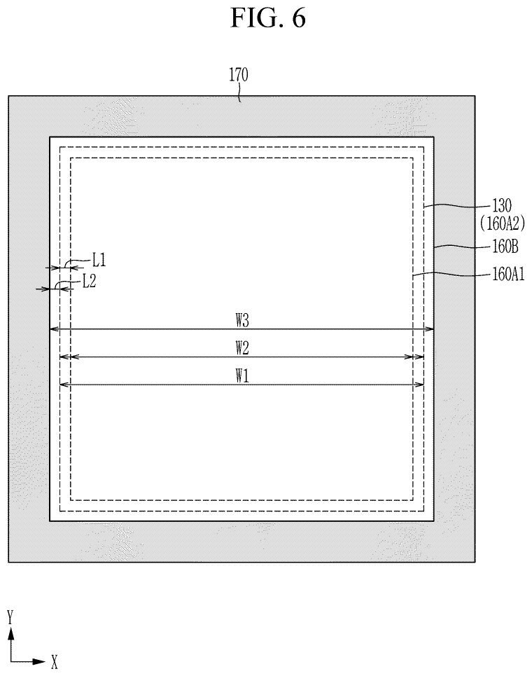

FIG. 5 is a cross-sectional view illustrating a high-bandwidth memory HBM 100C of an embodiment. FIG. 6 is a top plan view illustrating an upper surface of the high-bandwidth memory HBM 100C of FIG. 5 according to an embodiment.

Referring to FIGS. 5 and 6, each side surface 160AS of the side surfaces 160AS of the first portion 160A in the dummy die 160 may be recessed in the horizontal direction (X direction and/or Y direction) from the corresponding side surface 130S of the side surfaces 130S of the memory dies 130 (the memory stack S). Each side surface 160AS of the side surfaces 160AS of the first portion 160A may have a profile inclined from a lower surface 160A1 of the first portion 160A to a boundary (surface) 160A2 between the first portion 160A and the second portion 160B. The offset length of each side surface 160AS of the side surfaces 160AS of the first portion 160A offset inwardly in the horizontal direction (X direction and/or Y direction) from the corresponding side surface 130S of the side surfaces 130S of the memory dies 130 (the memory stack S) may become smaller as it goes from the lower surface 160A1 of the first portion 160A to the boundary surface 160A2 between the first portion 160A and the second portion 160B.

The memory dies 130 may have the first width W1 in the horizontal direction (X direction and/or Y direction). The first portion 160A of the dummy die 160 may have a second width W2 in the horizontal direction (X direction and/or Y direction). The second portion 160B of the dummy die 160 may have a third width W3 in the horizontal direction (X direction and/or Y direction). The second width W2 may be smaller than the first width W1. The second width W2 may increase as the distance from the memory stack S increases. For example, the second width W2 of the first portion 160A of the dummy die 160 may increase in a direction receding from the memory stack S upwards. The third width W3 may be larger than the first width W1. In FIG. 5, the second width W2 is illustrated as increasing as the distance from the memory stack S increases, but the inventive concept is not limited thereto, and in an embodiment, the second width W2 of the first portion 160A of the dummy die 160 decreases as the distance from the memory stack S increases, e.g., in the direction receding from the memory stack S upwards, or the second width W2 decreases and then increases as the distance from the memory stack S increases, e.g., in the direction receding from the memory stack S upwards, and the second width W2 increases and then decreases as the distance from the memory stack S increases, e.g., in the direction receding from the memory stack S upwards, and a combination thereof may be included within the scope of the present disclosure.

Each side surface 160AS of the side surfaces 160AS of the first portion 160A may be offset/shifted OS1 inwardly by a first length L1 in the horizontal direction (X direction and/or Y direction) from the corresponding side surface 130S of the side surfaces 130S of the memory dies 130 (memory stack S), e.g., in a plan view. The first length L1 may decrease from the lower surface 160A1 of the first portion 160A to the boundary surface 160A2 between the first portion 160A and the second portion 160B. The first length L1 may increase from the lower surface 160A1 of the first portion 160A to the boundary surface 160A2 between the first portion 160A and the second portion 160B. In an embodiment, the first length L1 may be in a range of about 0.5 mm to about 1.3 mm. Each side surface 160BS of the side surfaces 160BS of the second portion 160B may be offset/shifted OS2 outwardly by a second length L2 in the horizontal direction (X direction and/or Y direction) from the corresponding side surface 130S of the side surfaces 130S of the memory dies 130 (memory stack S), e.g., in a plan view. In an embodiment, the second length L2 may be in a range of about 0.5 mm to about 1.3 mm.

For contents/features other than those described above for the high-bandwidth memory HBM 100C of the embodiments of FIGS. 5 and 6, the contents/features described for the high-bandwidth memory HBM 100A of FIGS. 1 and 2 may be applied.

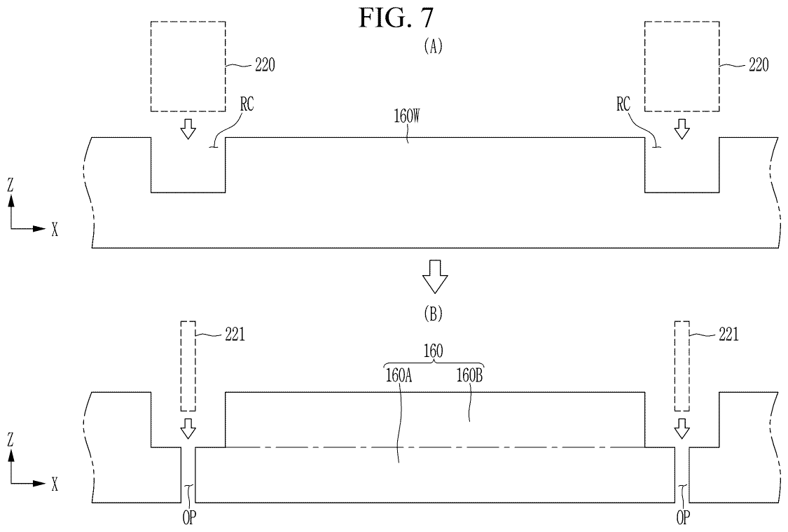

FIG. 7 is a cross-sectional view illustrating a method of manufacturing the dummy die 160 of FIG. 1 according to an embodiment. The method of FIG. 7 for manufacturing the dummy die 160 of the embodiment of FIG. 1 may also be applied to the method of manufacturing the dummy die 160 of the embodiment of FIG. 3.

Referring to step (A) of FIG. 7, a dummy wafer (dummy panel) 160W may be provided, and a first singulation process 220 may be performed on the dummy wafer 160W. The first singulation process 220 is not performed for the entire thickness of dummy wafer 160W in the vertical direction (Z direction), but may be performed for a portion of the thickness of the dummy wafer 160W in the vertical direction (Z direction). In an embodiment, the first singulation process 220 may be performed using a saw blade or a laser. After performing the first singulation process 220, recessed portions RC may be formed in the dummy wafer 160W.

Referring to step (B) of FIG. 7, a second singulation process 221 may be performed on the dummy wafer 160W to form an opening OP, e.g., through the dummy wafer 160W in the thickness direction. The opening OP formed by the second singulation process 221 may have a width smaller than the width of the recessed portions RC in the horizontal direction (X direction and/or Y direction) within the recessed portions RC of the dummy wafer 160W. In an embodiment, the second singulation process 221 may be performed using a saw blade or a laser. After performing the second singulation process 221, the dummy wafer 160W may be separated into dummy dies 160. Each of the dummy dies 160 may have a shape in which the first portion 160A having the second width W2 smaller than the first width W1 of the memory die 130 and the second portion 160B having the third width W3 larger than the first width W1 of the memory die 130 are integrally formed.

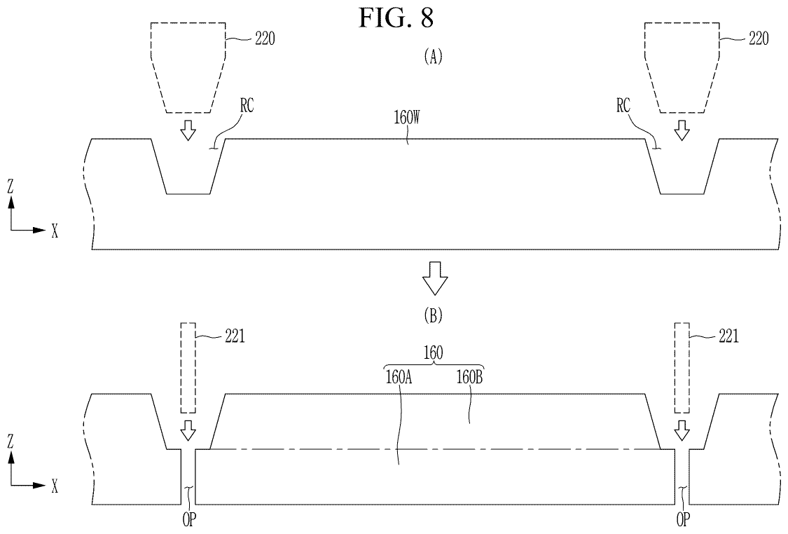

FIG. 8 is a cross-sectional view illustrating a method of manufacturing the dummy die 160 of FIG. 5 according to an embodiment.

Referring to step (A) of FIG. 8, the dummy wafer (dummy panel) 160W may be provided, and the first singulation process 220 may be performed on the dummy wafer 160W. The first singulation process 220 may form the recessed portions RC with inclined side surfaces in the dummy wafer 160W. The first singulation process 220 is not performed for the entire thickness of the dummy wafer 160W in the vertical direction (Z direction), but may be performed for a portion of the thickness of the dummy wafer 160W in the vertical direction (Z direction). In an embodiment, the first singulation process 220 may be performed using a saw blade or a laser.

Referring to step (B) of FIG. 8, the second singulation process 221 may be performed on the dummy wafer 160W to form an opening OP, e.g., through the dummy wafer 160W in the thickness direction of the dummy wafer 160W. The opening OP formed by the second singulation process 221 may have a width smaller than the width of the recessed portions RC in the horizontal direction (X direction and/or Y direction) within the recessed portions RC of the dummy wafer 160W. In an embodiment, the second singulation process 221 may be performed using a saw blade or a laser. After performing the second singulation process 221, the dummy wafer 160W may be separated into dummy dies 160. Each of the dummy dies 160 may have a shape in which the first portion 160A having the second width W2 smaller than the first width W1 of the memory die 130 and the second portion 160B having the third width W3 larger than the first width W1 of the memory die 130 are integrally formed. The length/size of the second width W2 may be gradually changed in the vertical direction (Z direction).

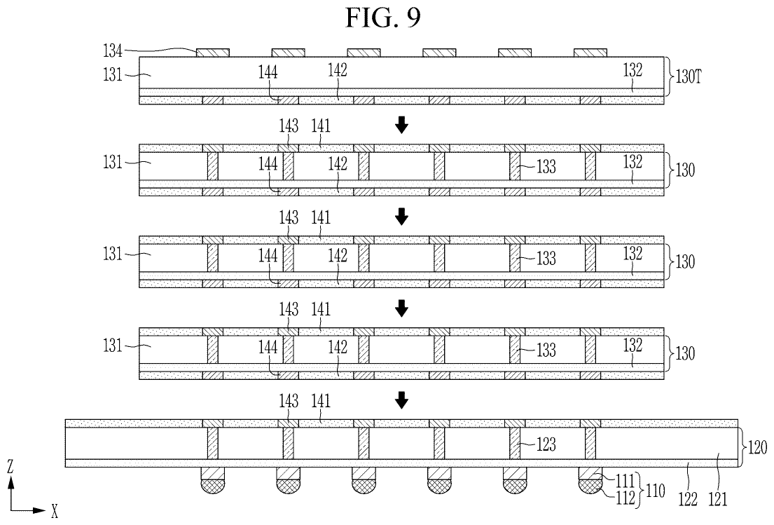

FIGS. 9 to 14 are cross-sectional views illustrating a method of forming the high-bandwidth memory HBM 100A of FIG. 1 according to an embodiment. The method of forming the high-bandwidth memory HBM 100A of the embodiment of FIG. 1 in FIGS. 9 to 14 may also be applied to the method of forming the high-bandwidth memory HBM 100B of the embodiment of FIG. 3 and the method of forming the high-bandwidth memory HBM 100A of the embodiment of FIG. 5.

FIG. 9 is a cross-sectional view illustrating a step of sequentially stacking the memory dies 130 on the base die 120.

Referring to FIG. 9, the hybrid bonding process may be performed sequentially to sequentially stack the memory dies 130 on the base die 120. Below, the hybrid bonding process of the base die 120 and the memory die 130 is described. The description of the hybrid bonding process of the base die 120 and the memory die 130 may be equally applied to the hybrid bonding process in the process of sequentially stacking the memory dies 130.

A chemical mechanical polishing (CMP) process may be performed prior to hybrid bonding. In an embodiment, surface roughness of each of the bonding surfaces where hybrid bonding occurs may be about 10 Å or less. Next, the bonding surface of the back side silicon layer 141 of the base die 120 and the bonding surface of the front side silicon layer 142 of the memory die 130 may be activated. In an embodiment, the bonding surface of the back side silicon layer 141 and the bonding surface of the front side silicon layer 142 may be surface-treated by plasma activation. Next, the first base die 120 and the memory die 130 may be aligned for hybrid bonding. Next, the activated bonding surface of the back side silicon layer 141 of the base die 120 and the activated bonding surface of the front side silicon layer 142 of the memory die 130 may be in contact and pre-bonded.

Then, the base die 120 and the memory die 130 may be hybrid-bonded. First, the back side silicon layer 141 of the base die 120 and the front side silicon layer 142 of the memory die 130 may be bonded by treatment. The treatment may strengthen the bonding between the back side silicon layer 141 of the pre-bonded base die 120 and the front side silicon layer 142 of the memory die 130.

Next, each of the back side bonding pads 143 of the base die 120 and each of the front side bonding pads 144 of the memory die 130 may be bonded by annealing.

After this, the same hybrid process may be performed to sequentially stack the memory dies 130.

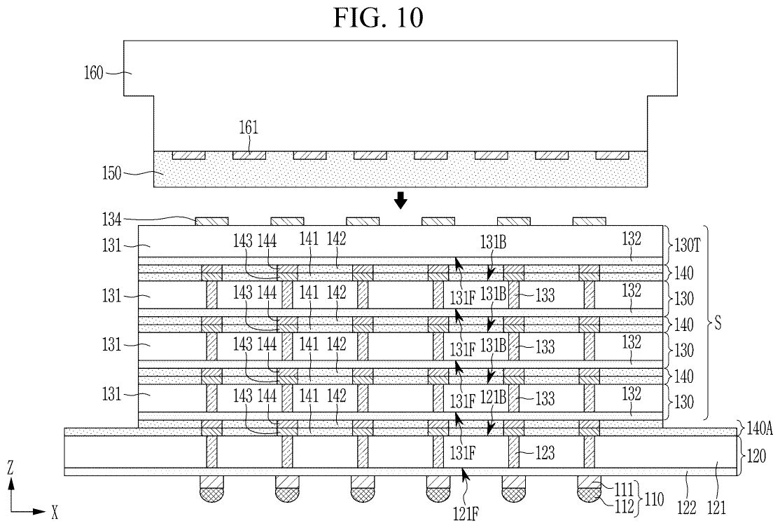

FIG. 10 is a cross-sectional view illustrating a step of aligning a dummy die 160 on a memory stack S.

Referring to FIG. 10, the dummy die 160 may be aligned on the memory stack S. The insulating member 150 may be attached to the lower surface of the dummy die 160, and the second pads 161 may be surrounded by the insulating member 150.

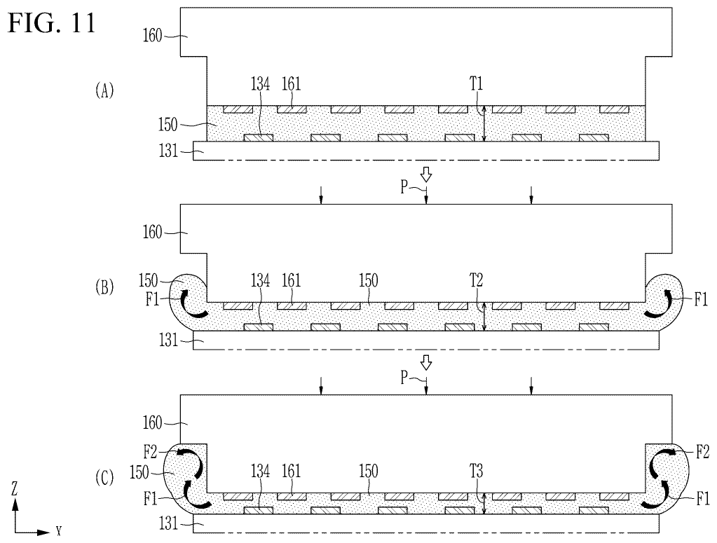

FIG. 11 is a cross-sectional view illustrating a step of attaching the dummy die 160 to the memory stack S.

Referring to FIG. 11, the dummy die 160 may be bonded on the memory stack S. The dummy die 160 may be bonded on the memory stack S by a thermal compression (TC) process.

FIG. 11 shows a step (A) in which the insulating member 150 on the lower surface of the dummy die 160 contacts the memory stack S before performing the thermal compression TC process. The insulating member 150 may contact the memory stack S and cover the first pads 134 on the memory stack S. In this case, the insulating member 150 may have a first thickness T1 in the vertical direction. The insulating member 150 prior to performing the thermal compression TC process may be in a gel state.

FIG. 11 shows a step (B) in which heat and pressure are applied to the insulating member 150 and the dummy die 160 by starting the thermal compression TC process. When heat is applied to the insulating member 150, the insulating member 150 may change from a gel state to a liquid state. Additionally, pressure P may be applied to the dummy die 160 on the insulating member 150. Due to the pressure P applied to the insulating member 150 in a liquid state, the insulating member 150 may flow outward between the memory stack S and the dummy die 160. Since the second width W2 in the horizontal direction (X direction and/or Y direction) of the first portion 160A of the dummy die 160 is smaller than the first width W1 in the horizontal direction (X direction and/or Y direction) of the memory die 130T positioned at the top of the memory stack S, the insulating member 150 flowing outward may flow upward rather than downward (see F1), e.g., due to surface energy between the side surface of the dummy die 160 and the insulating material/member 150. Due to the pressure P applied to the insulating member 150 in a liquid state, the insulating member 150 may have a second thickness T2 in the vertical direction that is smaller than the first thickness T1.

FIG. 11 illustrates a step (C) in which heat and pressure are applied to the insulating member 150 and to the dummy die 160 by performing the thermal compression TC process in continuation after step (B) of FIG. 11. Since the third width W3 in the horizontal direction (X direction and/or Y direction) of the second portion 160B of the dummy die 160 is larger than the second width W2 in the horizontal direction (X direction and/or Y direction) of the first portion 160A of the dummy die 160, the insulating member 150 that has flowed in the upward direction (see F1) may change direction and flow in the lateral direction (see F2). By continuously applying the pressure P to the insulating member 150 in a liquid state, the insulating member 150 may have a third thickness T3 in the vertical direction that is smaller than the second thickness T2.

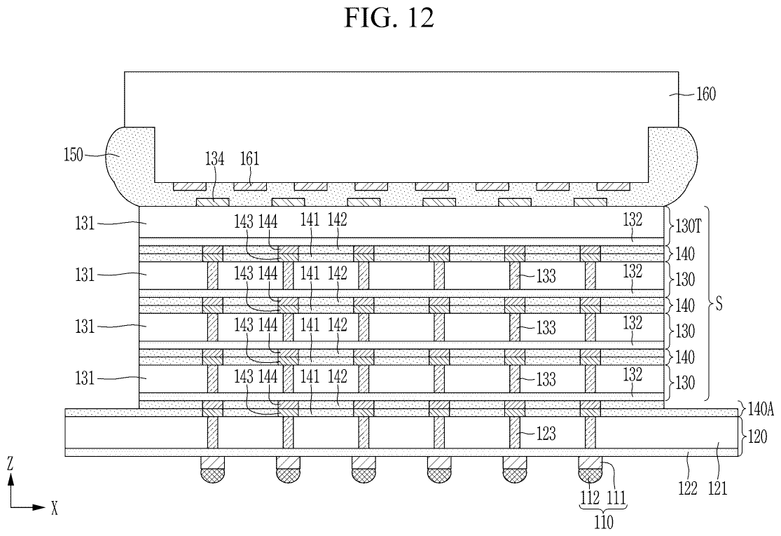

FIG. 12 is a cross-sectional view showing a step in which the thermal compression TC process is completed.

Referring to FIG. 12, the insulating member 150 that has flowed in the lateral direction (see F2) may be hardened and become a fillet after the thermal compression TC process is completed. The insulating member 150 is disposed and attached between the memory stack S and the dummy die 160, and may protect and electrically insulate the first pads 134 and the second pads 161, and connect the dummy die 160 to the memory stack S to be close enough to each other to be in thermal communication with each other.

According to the present disclosure, the dummy die 160 may include the first portion 160A having the second width W2 smaller than the first width W1 of the memory die 130, and the second portion 160B disposed on/above the first portion 160A and having the third width W3 larger than the first width W1 of the memory die 130. Accordingly, in the process of performing the thermal compression TC process to attach the dummy die 160 to the memory die 130T positioned at the top of the memory stack S, the insulating member 150 that overflows outward between the memory stack S and the dummy die 160 is primarily prevented from flowing downward by the memory stack S and secondarily prevented from flowing upward by the second portion 160B. This prevents the overflowed insulating member 150 from flowing downwards, causing separation between the memory dies 130, or creating cracks and adversely affecting the internal circuit of the base die 120 or the memory die 130. In addition, the overflowed insulating member 150 may flow upward, preventing the fillet from being exposed to the outside and oxidized, affecting the appearance of the final product.

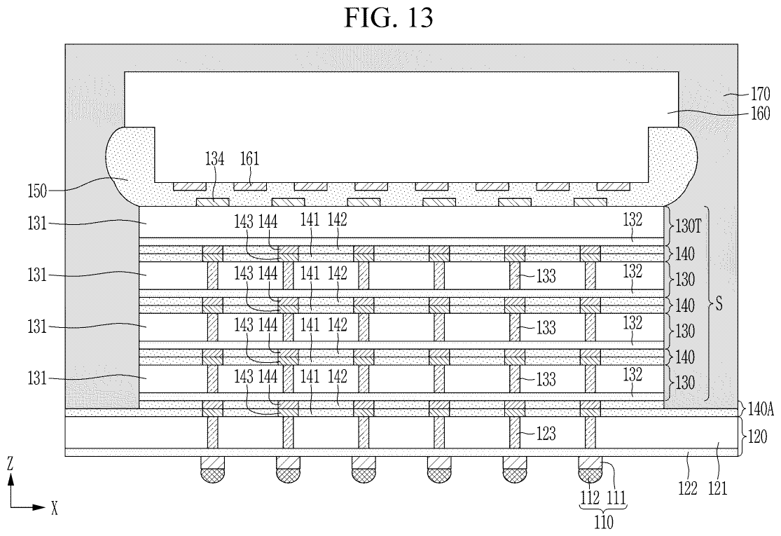

FIG. 13 is a cross-sectional view illustrating a step of molding the memory stack S, the insulating member 150, and the dummy die 160 on the base die 120.

Referring to FIG. 13, the memory stack S, the insulating member 150, and the dummy die 160 may be molded using the molding material 170 on the base die 120. For example, the process of molding with the molding material 170 may include a compression molding or transfer molding process. In an embodiment, the molding material 170 may include an epoxy molding compound (EMC).

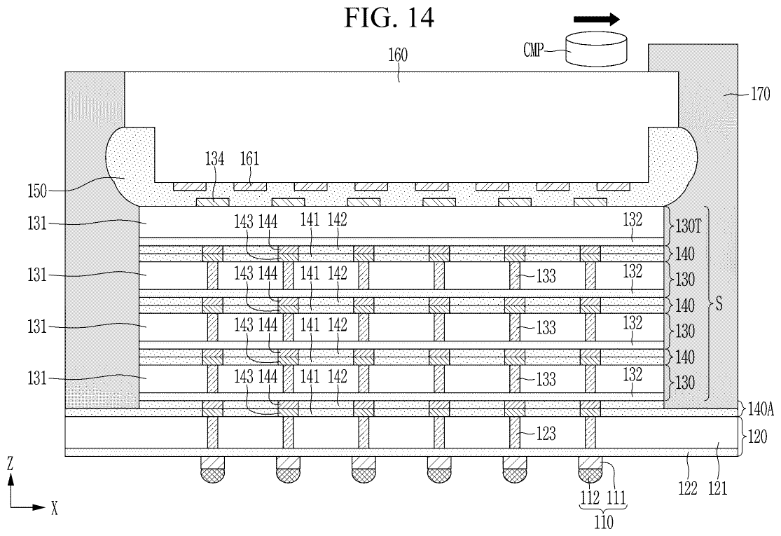

FIG. 14 is a cross-sectional view illustrating a step of performing the chemical mechanical polishing CMP process on the molding material 170.

Referring to FIG. 14, the chemical mechanical polishing CMP process may be performed to level the upper surface of the molding material 170. After performing the chemical mechanical polishing CMP process, the upper surface of the dummy die 160 is exposed, and the fillet of the insulating member 150 is not exposed to the outside.

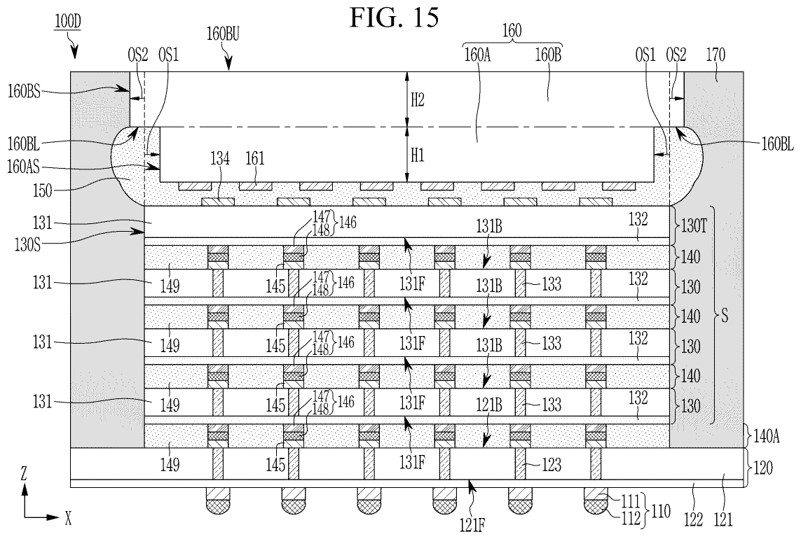

FIG. 15 is a cross-sectional view illustrating a high-bandwidth memory HBM 100D of an embodiment.

Referring to FIG. 15, the first interconnection structure 140A may be disposed between the back side 121B of the die base 121 and the memory stack S. The second interconnection structures 140 may be alternately stacked with the memory dies 130. Each of the second interconnection structures 140 may be positioned between a back side 131B of a memory die base 131 of a memory die 130 and a front side structure 132 of an adjacent memory die 130. The first interconnection structure 140A and the second interconnection structures 140 may each include bonding pads 145, second bump structures 146, and an insulating member 149. As the second bump structures 146 are newly defined, the bump structures 110 may be named first bump structures 110.

Each of the bonding pads 145 of the first interconnection structure 140A may be disposed between a corresponding first through silicon via TSV 123 among the first through silicon vias TSV 123 and a corresponding second bump structure 146 among the second bump structures 146. Each of the bonding pads 145 of the first interconnection structure 140A may electrically connect the corresponding first through silicon via TSV 123 among the first through silicon vias TSV 123 to the corresponding second bump structure 146 among the second bump structures 146. Each of the bonding pads 145 of the second interconnection structure 140 may be disposed between a corresponding second through silicon via TSV 133 among the second through silicon vias TSV 133 and the corresponding second bump structure 146 among the second bump structures 146. Each of the bonding pads 145 of the second interconnection structure 140 may electrically connect the corresponding second through silicon via TSV 133 among the second through silicon vias TSV 133 to the corresponding second bump structure 146 among the second bump structures 146. In an embodiment, the bonding pads 145 may include at least one of copper, aluminum, tungsten, nickel, gold, tin, titanium, and an alloy thereof.

The second bump structures 146 may be disposed between the base die 120 and the memory stack S, and/or between one memory die 130 and another adjacent memory die 130. Each of the second bump structures 146 may be disposed between the corresponding bonding pad 145 among the bonding pads 145 and a corresponding wiring among the wirings of the front side structure 132 of the memory die 130. Each of the second bump structures 146 may include a bump pillar 147 and a solder ball 148. In an embodiment, the second bump structures 146 may include or may be microbumps.

Each of the bump pillars 147 may be disposed between a corresponding solder ball 148 among the solder balls 148 and a corresponding wiring among the wirings of the front side structure 132 of the memory die 130. Each of the bump pillars 147 may electrically connect a corresponding wiring among the wirings of the front side structure 132 of the memory die 130 to the corresponding solder ball 148 among the solder balls 148. Each of the solder balls 148 may be disposed between a corresponding bonding pad 145 among the bonding pads 145 and a corresponding bump pillar 147 among the bump pillars 147. Each of the solder balls 148 may electrically connect a corresponding bump pillar 147 among the bump pillars 147 to a corresponding bonding pad 145 among the bonding pads 145. In an embodiment, the bump pillar 147 may be formed of copper, or a copper alloy including silver, chromium, nickel, tin, gold, and a combination thereof. In an embodiment, the solder ball 148 may include at least one of tin, silver, lead, nickel, copper, and an alloy thereof.

Each of the insulating members 149 may be disposed between the base die 120 and the memory stack S, or between one memory die 130 and an adjacent memory die 130. Each of the insulating members 149 may surround and insulate the bonding pads 145 and the second bump structures 146. In an embodiment, each of the insulating members 149 may include or may be the non-conductive film NCF.

In addition to the above-described contents/features, the contents/features of the high-bandwidth memory HBM 100D of FIG. 15 may be applied to the contents/embodiments described for the high-bandwidth memory HBM 100A of FIGS. 1 and 2, the contents/embodiments described for the high-bandwidth memory HBM 100B of FIGS. 3 and 4, the contents/embodiments described for the high-bandwidth memory HBM 100C of FIGS. 5 and 6, and the method of manufacturing the dummy die 160 of the embodiments described with respect to FIGS. 7 and 8.

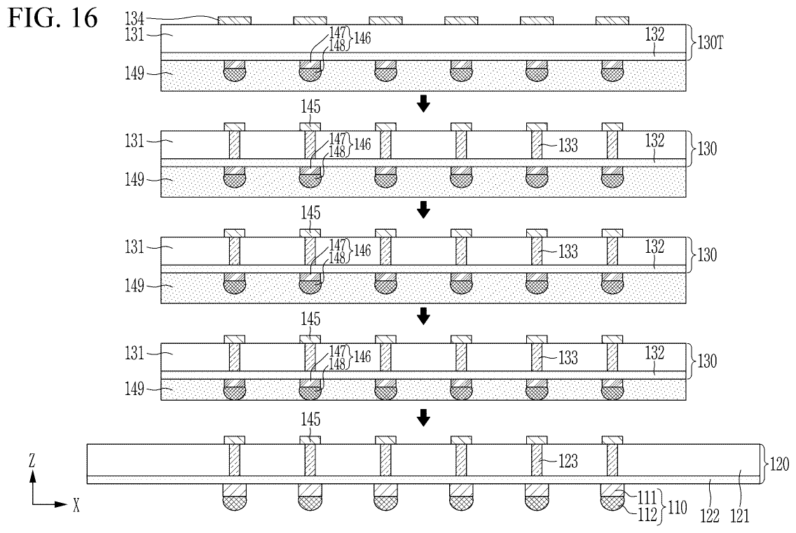

FIGS. 16 to 20 are cross-sectional views illustrating a method of forming the high-bandwidth memory HBM 100D of FIG. 15 according to an embodiment.

FIG. 16 is a cross-sectional view illustrating a step of sequentially stacking the memory dies 130 on the base die 120.

Referring to FIG. 16, each memory die 130 may be sequentially bonded on the base die 120 by the thermal compression TC process. The insulating member 149 is attached to the lower surface of each memory die 130, and the second bump structures 146 on the lower surface of the memory die 130 may be surrounded by the insulating member 149.

By the thermal compression TC process, each of the second bump structures 146 may be bonded to the corresponding bonding pad 145 among the bonding pads 145. The insulating member 149 is in a gel state before performing the thermal compression TC process, and during the TC process, and may change from a gel state to a liquid state as heat is applied and finally to a cured state.

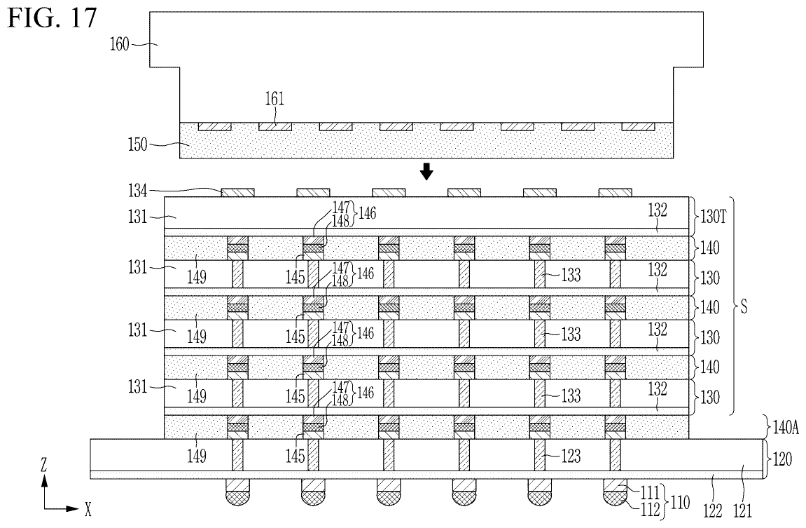

FIG. 17 is a cross-sectional view illustrating a step of aligning the dummy die 160 on the memory stack S.

Referring to FIG. 17, the dummy die 160 may be aligned on the memory stack S. The insulating member 150 may be attached to the lower surface of the dummy die 160, and the second pads 161 may be surrounded by the insulating member 150.

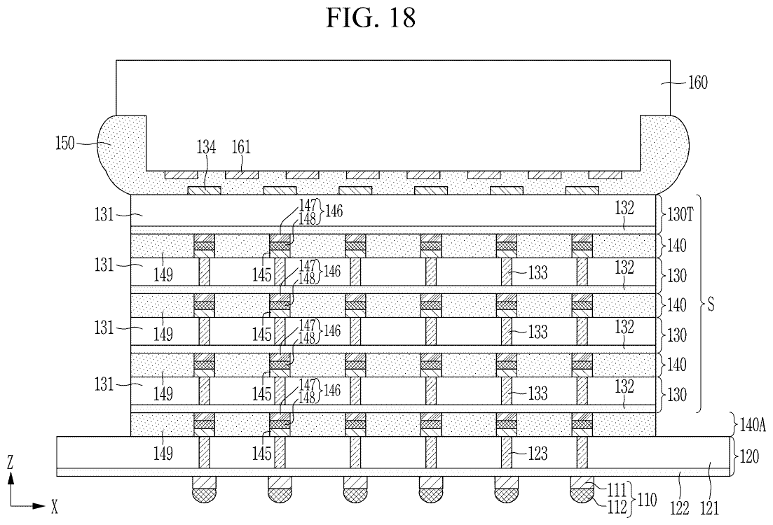

FIG. 18 is a cross-sectional view illustrating a step of attaching the dummy die 160 to the memory stack S.

Referring to FIG. 18, the dummy die 160 may be bonded on the memory stack S. The dummy die 160 may be bonded on the memory stack S by a thermal compression (TC) process. The process of bonding the dummy die 160 on the memory stack S may be the same as the above description with respect to FIG. 11 and FIG. 12. The insulating member 150 may be attached between the memory stack S and the dummy die 160 and may surround the first pads 134 and the second pads 161.

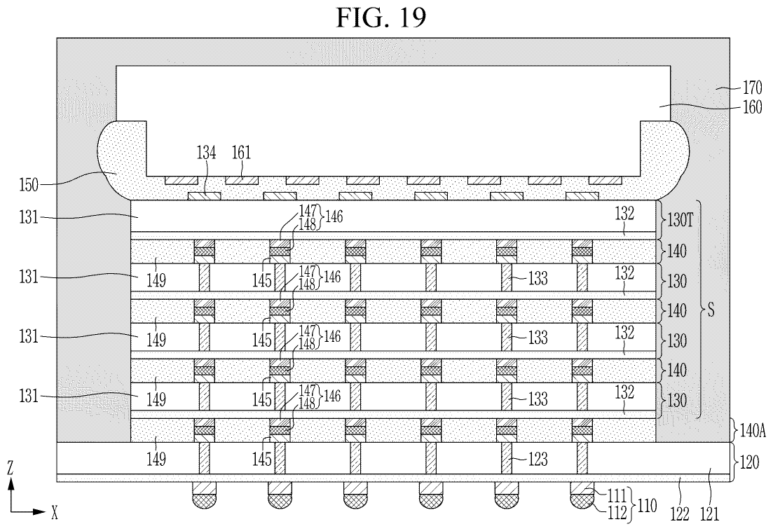

FIG. 19 is a cross-sectional view illustrating a step of molding the memory stack S, the insulating member 150, and the dummy die 160 on the base die 120.

Referring to FIG. 19, on the base die 120, the memory stack S, the insulating member 150, and the dummy die 160 may be molded using the molding material 170. For example, the process of molding with the molding material 170 may include a compression molding or transfer molding process. In an embodiment, the molding material 170 may include an epoxy molding compound (EMC).

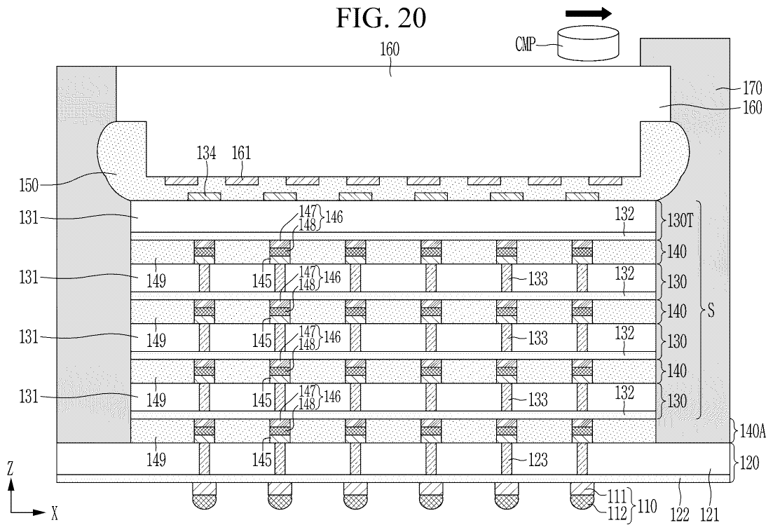

FIG. 20 is a cross-sectional view illustrating a step of performing the chemical mechanical polishing CMP process on the molding material 170.

Referring to FIG. 20, the chemical mechanical polishing CMP process may be performed to level the upper surface of the molding material 170. After performing the chemical mechanical polishing CMP process, the upper surface of the dummy die 160 is exposed, and the fillet of the insulating member 150 is not exposed to the outside.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While the embodiments of the present disclosure have been described in detail, it is to be understood that the disclosure is not limited to the disclosed embodiments, but on the contrary, is intended to cover various modifications and equivalent arrangements included within the spirit and scope of the appended claims.

What is claimed is:

1. A high-bandwidth memory, comprising:
a base die;
a semiconductor stack including a plurality of core dies stacked on the base die, wherein the plurality of core dies has a first width in a horizontal direction;
a dummy die on the semiconductor stack, wherein the dummy die comprises:
a first portion having a second width in the horizontal direction; and
a second portion above the first portion and having a third width in the horizontal direction,
the second width is smaller than the first width,
the third width is greater than or equal to the first width;
an insulating layer between the semiconductor stack and the dummy die; and
a molding material formed on the base die and covering side surfaces of the semiconductor stack, the dummy die, and the insulating layer.

2. The high-bandwidth memory of claim 1, wherein
the whole of the first portion of the dummy die overlaps the semiconductor stack in a vertical direction.

3. The high-bandwidth memory of claim 2, wherein
the whole of the semiconductor stack overlaps the second portion of the dummy die in a vertical direction.

4. The high-bandwidth memory of claim 1, wherein
the insulating layer comprises a non-conductive film.

5. The high-bandwidth memory of claim 4, wherein
the insulating layer comprises an inorganic filler, and
the inorganic filler includes alumina.

6. The high-bandwidth memory of claim 1, further comprising
a plurality of first pads disposed on the semiconductor stack.

7. The high-bandwidth memory of claim 6, further comprising
a plurality of second pads disposed on a surface of the dummy die facing the semiconductor stack.

8. The high-bandwidth memory of claim 7, wherein
the insulating layer covers the plurality of first pads and the plurality of second pads.

9. The high-bandwidth memory of claim 7, wherein
the plurality of second pads are spaced apart from the plurality of first pads.

10. The high-bandwidth memory of claim 7, wherein
the dummy die is thermally connected to the semiconductor stack through the plurality of first pads, the plurality of second pads, and the insulating layer.

11. The high-bandwidth memory of claim 1, wherein
the dummy die comprises a heat dissipation structure.

12. The high-bandwidth memory of claim 1, wherein
the second width increases in a direction receding from the semiconductor stack.

13. A high-bandwidth memory, comprising:
a buffer die;
a memory stack including a plurality of memory dies stacked on the buffer die;
a dummy die on the memory stack, wherein the dummy die comprises:
a first portion, each of side surfaces of the first portion being recessed in a horizontal direction from a corresponding side surface among side surfaces of the plurality of memory dies, the corresponding side surface of the plurality of memory dies facing the same direction as the side surface of the first portion recessed from the corresponding side surface of the plurality of memory dies; and
a second portion above the first portion, each of side surfaces of the second portion protruding in a horizontal direction from a corresponding side surface among the side surfaces of the plurality of memory dies, the corresponding side surface of the plurality of memory dies facing the same direction as the side surface of the second portion protruding from the corresponding side surface of the plurality of memory dies;
an insulating layer between the memory stack and the dummy die; and
a molding material formed on the buffer die and covering side surfaces of the memory stack, the dummy die, and the insulating layer.

14. The high-bandwidth memory of claim 13, wherein
the insulating layer contacts at least a part of each of the side surfaces of the first portion.

15. The high-bandwidth memory of claim 13, wherein
the second portion of the dummy die comprises
a first surface exposed to the outside of the molding material; and
a second surface opposite to the first surface and extending between the side surfaces of the first portion and the side surfaces of the second portion,
and at least a part of the second surface contacts the insulating layer.

16. A high-bandwidth memory, comprising:
a base die;
a semiconductor stack including a plurality of core dies stacked on the base die, wherein the semiconductor stack comprises a plurality of core dies and a plurality of interconnection structures, and the plurality of core dies and the plurality of interconnection structures are alternately stacked;
an insulating layer on the semiconductor stack;
a dummy die on the insulating layer, wherein the dummy die comprises:
a first section, each of side surfaces of the first section being offset inwardly in a horizontal direction by a first length from a corresponding side surface among side surfaces of the plurality of core dies; and
a second section above the first section, each of side surfaces of the second section being offset outwardly by a second length from a corresponding side surface among the side surfaces of the plurality of core dies; and
a molding material formed on the base die and covering side surfaces of the semiconductor stack, the dummy die, and the insulating layer.

17. The high-bandwidth memory of claim 16, wherein
the first length and the second length are in a range from 0.5 mm to 1.3 mm.

18. The high-bandwidth memory of claim 16, wherein
the first section of the dummy die has a first height in a vertical direction,
the second section of the dummy die has a second height in the vertical direction, and
a ratio of the first height to the second height is in a range from 1:9 to 9:1.

19. The high-bandwidth memory of claim 16, wherein
each of the interconnection structures comprises
a first silicon layer;
a second silicon layer disposed on the first silicon layer and directly bonded to the first silicon layer;
a plurality of first bonding pads penetrating the first silicon layer; and
a plurality of second bonding pads penetrating the second silicon layer,
wherein each of the first bonding pads is directly bonded to a corresponding second bonding pad of the plurality of second bonding pads.

20. The high-bandwidth memory of claim 16, wherein
each of the interconnection structures comprises
bump structures, each of the bump structures comprises a bump pillar and a solder; and
a non-conductive film surrounding the bump structures.
